(19) United States
(12) Patent Application Publication
(10) Pub. No.: US 2024/0222290 A1
(43) Pub. Date: Jul. 4, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Fang-Lin TSAI, Taichung City (TW); Wei-Son TSAI, Taichung City (TW); Kun-Yuan LUO, Taichung City (TW); Pei-Geng WENG, Taichung City (TW); Ching-Hung TSENG, Taichung City (TW)

(73) Assignee: SILICONWARE PRECISION INDUSTRIES CO., LTD., Taichung City (TW)

(21) Appl. No.: 18/310,815

(22) Filed: May 2, 2023

(30) Foreign Application Priority Data
Dec. 29, 2022 (TW) 111150723

(51) Int. Cl. H01L 23/552; H01L 23/00; H01L 23/31

(52) U.S. Cl. CPC H01L 23/552; H01L 23/3128; H01L 24/16; H01L 24/32; H01L 2224/16225; H01L 2224/32225; H01L 2924/1811; H01L 2924/3025

(57) ABSTRACT

An electronic package is provided, in which an electronic element and a plurality of shielding pillars are embedded in an encapsulating layer, a shielding layer is formed on one surface of the encapsulating layer to cover the electronic element and is in contact with and connected to the plurality of shielding pillars, and a circuit structure is formed on the other surface of the encapsulating layer to electrically connect to the electronic element. Therefore, when the electronic package is disposed on a circuit board, the design of the shielding layer and the plurality of shielding pillars can provide the electronic element with heat dissipation and shielding effects without a metal cover arranged on the electronic element.

### BACKGROUND

### 1. Technical Field

The present disclosure relates to a semiconductor device and manufacturing method thereof, and more particularly, to an electronic package with electronic element stacking structure and manufacturing method thereof.

### 2. Description of Related Art

With the vigorous development of the electronic industry, electronic products are also gradually developing towards the trend of multi-function and high performance. Technologies currently used in the field of chip packaging include, for example, flip-chip packaging modules such as chip scale package (CSP), direct chip attached (DCA), or multi-chip module (MCM).

FIG. 1 is a schematic cross-sectional view of a conventional semiconductor package 1. As shown in FIG. 1, the semiconductor package 1 is provided with a semiconductor chip 11 disposed on a substrate structure 10 having a dielectric layer 100 and a circuit layer 101 in a flip-chip manner (via conductive bumps 110), and then the semiconductor chip 11 is encapsulated by an encapsulating layer 15. Afterwards, the semiconductor package 1 is disposed on a circuit board 19 with the substrate structure 10 thereof via a plurality of solder balls 17. Then, a top sheet 130 of a metal cover 13 is bonded onto the encapsulating layer 15 via a heat dissipation layer 12 to cover the semiconductor chip 11, and supporting legs 131 of the metal cover 13 are disposed on the circuit board 19 via a metal glue 14.

In the conventional semiconductor package 1, the metal glue 14 can be bonded to a grounding pad (not shown) of the circuit board 19, so that the metal cover 13 can be used as a shielding structure to prevent the semiconductor chip 11 from electromagnetic interference (EMI).

In the conventional semiconductor package 1, the heat dissipation and shielding functions for the semiconductor chip 11 are provided by the configuration of the metal cover 13. However, the metal cover 13 occupies a large use area of the circuit board 19, which is not only hard to reduce the use area of the circuit board to achieve the purpose of integration, but also difficult to configure other functional electronic elements to increase the functions of electronic products.

Therefore, there is a need for a solution that addresses the aforementioned shortcomings in the prior art.

### SUMMARY

In view of the aforementioned shortcomings of the prior art, the present disclosure provides an electronic package, which comprises: an encapsulating layer having a first surface and a second surface opposing the first surface; an electronic element embedded in the encapsulating layer; a shielding layer formed on the first surface of the encapsulating layer and covering the electronic element; a plurality of shielding pillars embedded in the encapsulating layer and in communication with the first surface and the second surface to contact and connect the shielding layer; and a circuit structure formed on the second surface of the encapsulating layer and electrically connected to the electronic element.

The present disclosure further provides a method of manufacturing an electronic package, the method comprises: forming a shielding layer on a carrier; disposing an electronic element on the shielding layer, and forming a plurality of shielding pillars on the shielding layer, wherein the plurality of shielding pillars are in contact with and connected to the shielding layer; forming an encapsulating layer on the shielding layer, wherein the electronic element and the plurality of shielding pillars are covered by the encapsulating layer, wherein the encapsulating layer is defined with a first surface and a second surface opposing the first surface, and the encapsulating layer is bonded onto the shielding layer with the first surface of the encapsulating layer; forming a circuit structure on the second surface of the encapsulating layer, wherein the circuit structure is electrically connected to the electronic element; and removing the carrier.

In the aforementioned electronic package and method, the present disclosure further comprises forming a bonding layer between the shielding layer and the electronic element.

In the aforementioned electronic package and method, the shielding layer is in contact with the electronic element.

In the aforementioned electronic package and method, a width of each of the plurality of shielding pillars is greater than a thickness of the shielding layer.

In the aforementioned electronic package and method, the electronic element is surrounded by the plurality of shielding pillars.

In the aforementioned electronic package and method, the present disclosure further comprises forming a shielding portion on the circuit structure, wherein the shielding portion is connected to the plurality of shielding pillars. For example, the shielding portion is formed on side surfaces of the circuit structure. Alternatively, the shielding portion is arranged obliquely relative to the second surface of the encapsulating layer. The present disclosure further comprises forming an insulating protection layer to cover at least part of the shielding portion.

In the aforementioned electronic package and method, a maximum width of the circuit structure is less than a width of the second surface of the encapsulating layer.

As can be understood from the above, in the electronic package of the present disclosure and manufacturing method thereof, the conventional metal cover is replaced by the design of the shielding layer and the shielding pillars. Therefore, compared with the prior art, after the electronic package of the present disclosure is disposed on the circuit board, the electronic package can provide heat dissipation and shielding effect to the electronic element without disposing a conventional metal cover. Thus, the electronic package of the present disclosure is conducive to reduce the use area of the circuit board and achieve the purpose of integration, so that electronic products meet the requirement of miniaturization.

On the other hand, if the use area of the circuit board is maintained, when the electronic package is disposed on the circuit board, other functional electronic elements can be configured without disposing a conventional metal cover, so the function of electronic products can be increased to facilitate the multifunctional purpose of electronic products.

### BRIEF DESCRIPTION OF THE DRAWINGS

FIG. 1 is a schematic cross-sectional view of a conventional semiconductor package.

FIG. 2A-1, FIG. 2B, FIG. 2C, FIG. 2D, FIG. 2E and FIG. 2F-1 are schematic cross-sectional views illustrating a method of manufacturing an electronic package according to a first embodiment of the present disclosure.

FIG. 2A-2 is a schematic top view of FIG. 2A-1.

FIG. 2F-2 is a schematic cross-sectional view showing another aspect of FIG. 2F-1.

FIG. 2G is a schematic cross-sectional view showing a subsequent process of FIG. 2F-1.

FIG. 3A and FIG. 3B-1 are schematic cross-sectional views illustrating a method of manufacturing an electronic package according to a second embodiment of the present disclosure.

FIG. 3B-2 is a schematic cross-sectional view showing another aspect of FIG. 3B-1.

FIG. 3C is a schematic cross-sectional view showing the other aspect of FIG. 3B-1.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

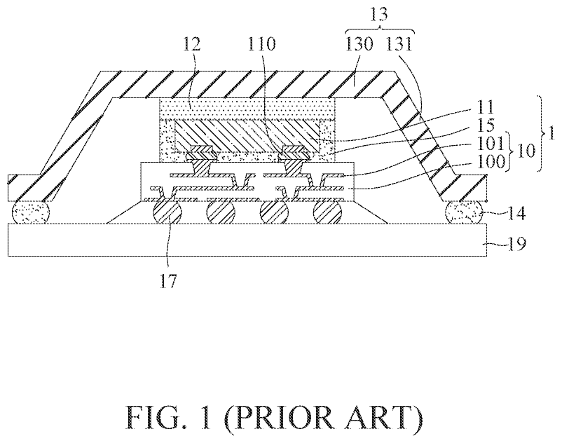

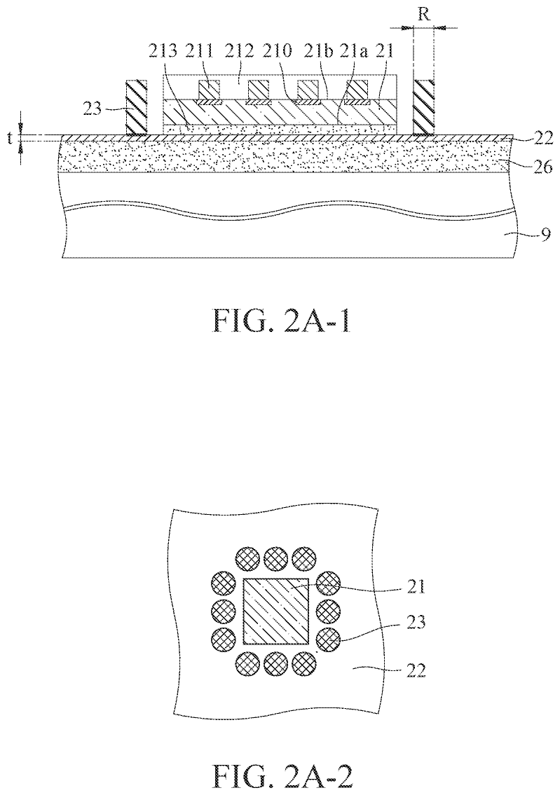

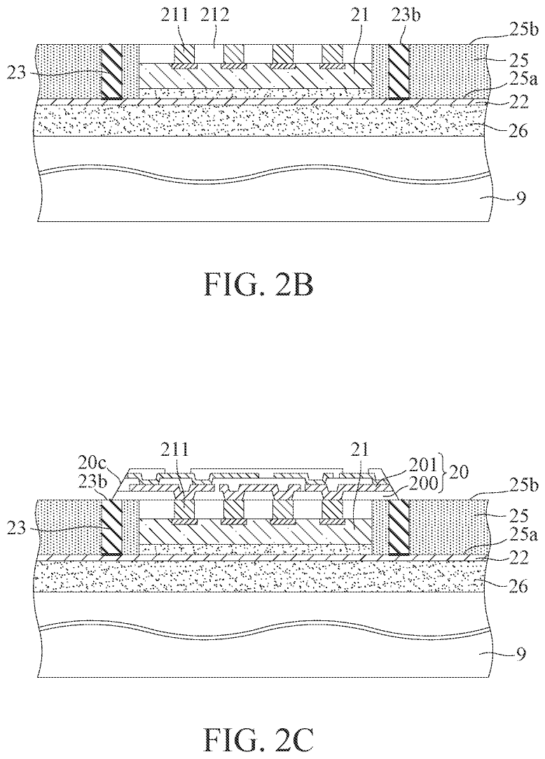

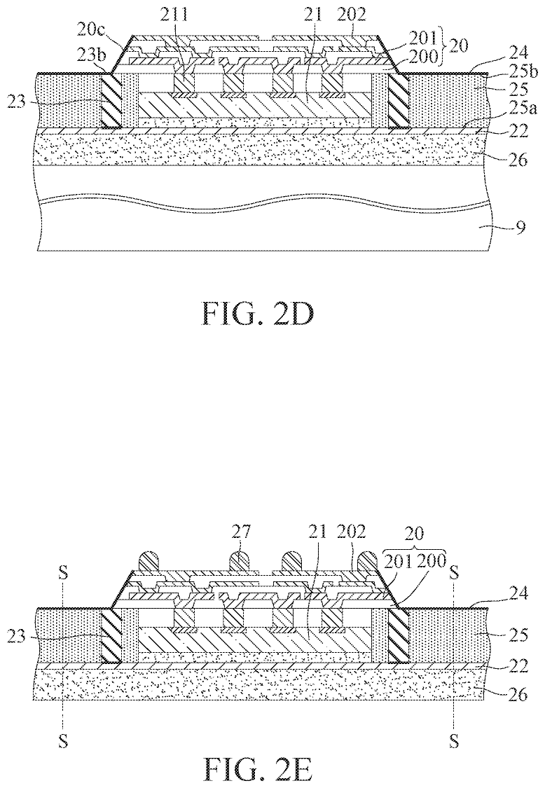

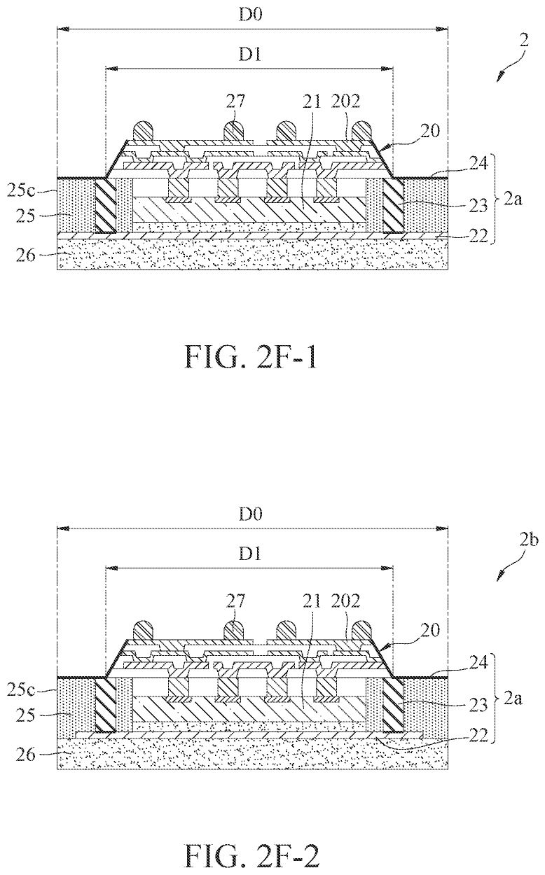

FIG. 2A-1, FIG. 2B, FIG. 2C, FIG. 2D, FIG. 2E and FIG. 2F-1 are schematic cross-sectional views illustrating a method of manufacturing an electronic package 2 according to a first embodiment of the present disclosure.

As shown in FIG. 2A-1, a carrier 9 having an insulating base layer 26 and a shielding layer 22 is provided, and a plurality of shielding pillars 23 are formed on the shielding layer 22, and at least one electronic element 21 is disposed on the shielding layer 22.

In an embodiment, the carrier 9 is a circular plate made of semiconductor material such as glass, on which the insulating base layer 26 is formed, and the shielding layer 22 is formed on the insulating base layer 26. For example, the insulating base layer 26 is made of polybenzoxazole (PBO), polyimide (PI), prepreg (PP), or other dielectric materials, and the shielding layer 22 is a copper layer.

Moreover, the electronic element 21 is a semiconductor element, such as an active element, a passive element, or a combination of the active element and the passive element. The active element may be a semiconductor chip, and the passive element may be a resistor, a capacitor, or an inductor. For example, the electronic element 21 is a semiconductor chip and has an active surface 21a and an inactive surface 21b opposing the active surface 21a. The active surface 21a has a plurality of electrode pads 210 for arranging conductors 211 such as copper blocks and/or solder bumps, and an insulating layer 212 made of such as a dielectric material is formed on the active surface 21a to cover the conductors 211.

Also, the electronic element 21 is adhesively fixed on the shielding layer 22 with the inactive surface 21b of the electronic element 21 by a bonding layer 213 such as glue, so that the bonding layer 213 is arranged between the shielding layer 22 and the electronic element 21. For example, the bonding layer 213 is formed on a lower side of the electronic element 21 first, and then the electronic element 21 is adhesively fixed on the shielding layer 22. It should be understood that the bonding layer 213 may also be formed on the shielding layer 22 first, and then the electronic element 21 is adhesively fixed on the bonding layer 213.

In addition, the shielding pillars 23 are in contact with and disposed on the shielding layer 22 and surround the electronic element 21 (as shown in FIG. 2A-2), and the shielding pillars 23 are made of metal material (such as copper) or solder material. For example, a width R of the shielding pillar 23 is greater than a thickness t of the shielding layer 22.

As shown in FIG. 2B, an encapsulating layer 25 is formed on the shielding layer 22, so that the electronic element 21 and the shielding pillars 23 are covered by the encapsulating layer 25.

In an embodiment, the encapsulating layer 25 is defined with a first surface 25a and a second surface 25b opposing the first surface 25a, so that the encapsulating layer 25 is bonded on the shielding layer 22 with the first surface 25a of the encapsulating layer 25.

Furthermore, the encapsulating layer 25 is made of an insulating material, such as polyimide (PI), dry film, epoxy resin, molding compound, or other packaging materials. The encapsulating layer 25 can be formed on the shielding layer 22 by lamination or molding. Also, part of the material of the shielding pillars 23, part of the material of the insulating layer 212 (part of the material of the conductors 211 can be removed according to requirements) and part of the material of the second surface 25b of the encapsulating layer 25 can be removed by a leveling process such as grinding, so that end surfaces 23b of the shielding pillars 23, an exterior surface of the insulating layer 212 and exterior surfaces of the conductors 211 are flush with the second surface 25b of the encapsulating layer 25, so that the end surfaces 23b of the shielding pillars 23 and the exterior surfaces of the conductors 211 of the electronic element 21 are exposed from the encapsulating layer 25. It should be understood that there are many ways to expose the shielding pillars 23 and the conductors 211 from the encapsulating layer 25, and the present disclosure is not limited to the above.

As shown in FIG. 2C, a circuit structure 20 is formed on one region of the second surface 25b of the encapsulating layer 25, so that the end surfaces 23b of the shielding pillars 23 are still exposed from the other region of the second surface 25b of the encapsulating layer 25, and the circuit structure 20 is electrically connected to the plurality of conductors 211 of the electronic element 21, wherein side surfaces 20c of the circuit structure 20 are non-perpendicular relative to the second surface 25b of the encapsulating layer 25.

In an embodiment, the circuit structure 20 comprises a plurality of dielectric layers 200, and a plurality of circuit layers 201 disposed on the plurality of dielectric layers 200 and electrically connected to the conductors 211. The circuit layers 201 are for instance of redistribution layer (RDL) specification, and the outermost circuit layer 201 is exposed from the outermost dielectric layer 200. Alternatively, the circuit structure 20 may also merely comprise a single dielectric layer 200 and a single circuit layer 201.

Moreover, the material forming the circuit layer 201 is copper, and the material forming the dielectric layer 200 is polybenzoxazole (PBO), polyimide (PI), prepreg (PP), or other dielectric materials.

Also, the side surfaces 20c of the circuit structure 20 are inclined relative to the second surface 25b of the encapsulating layer 25, so that the shape of the circuit structure 20 is trapezoidal or cone-shaped.

As shown in FIG. 2D, a plurality of electrical contact pads 202 electrically connected to the circuit layer 201 are formed on the outermost dielectric layer 200 of the circuit structure 20, and a shielding portion 24 is formed on the other region of the second surface 25b of the encapsulating layer 25 and the side surfaces 20c of the circuit structure 20, so that the shielding portion 24 is in contact with and covers the end surfaces 23b of the shielding pillars 23, and the shielding portion 24 extends continuously from the second surface 25b of the encapsulating layer 25 to the outermost dielectric layer 200.

In an embodiment, the shielding portion 24 is made of a metal material such as copper and is formed on the other region of the second surface 25b of the encapsulating layer 25 and the side surfaces 20c of the circuit structure 20 by sputtering, evaporation, electroplating, chemical plating (electroless plating), foiling, or other coating methods, so that the shielding portion 24 is arranged obliquely relative to the second surface 25b of the encapsulating layer 25.

Furthermore, the electrical contact pads 202 are of RDL specification. For example, a metal material such as copper is formed on the entire surface of the dielectric layer 200 by electroplating, sputtering, deposition, or other coating methods, and then a patterning process is performed to remove excess metal material by etching, so that the remaining metal material may be served as the electrical contact pads 202. Therefore, the shielding portion 24 and the electrical contact pads 202 can be fabricated together to greatly reduce the process time.

Also, the shielding portion 24 can be in contact with the circuit layer 201 exposed from the side surfaces 20c when the circuit layer 201 is exposed from the side surfaces 20c of the circuit structure 20, so that the shielding portion 24 is grounded and connected to the circuit layer 201. Alternatively, the shielding portion 24 can be directly connected to the electrical contact pads 202 so that the shielding portion 24 is grounded and connected to the electrical contact pads 202. It should be understood that the shielding portion 24 can also be in contact with the circuit layer 201 exposed from the side surfaces 20c and the electrical contact pads 202 simultaneously, so that the shielding portion 24 is grounded and connected to the circuit layer 201 and the electrical contact pads 202.

As shown in FIG. 2E, a plurality of conductive elements 27 are formed on the electrical contact pads 202, and then the carrier 9 is removed to expose the insulating base layer 26.

In an embodiment, the conductive elements 27 are solder balls, metal pillars, or other structures suitable for external elements. For example, an under bump metallurgy (UBM) layer (not shown) may be formed on the electrical contact pads 202 to facilitate bonding the conductive elements 27.

As shown in FIG. 2F-1, a singulation process is performed along cutting paths S shown in FIG. 2E to obtain a plurality of the electronic packages 2, and a maximum width D1 of the circuit structure 20 is less than a width DO of the second surface 25b of the encapsulating layer 25.

In an embodiment, in the electronic package 2, the shielding portion 24, the shielding layer 22 and the shielding pillars 23 are connected together to serve as a shielding structure 2a to protect the electronic element 21 from electromagnetic interference (EMI).

Furthermore, the shielding layer 22 is bonded to the electronic element 21, so that the shielding layer 22 can also be used as a heat dissipation layer to facilitate heat dissipation of the electronic element 21.

Also, the shielding layer 22 is exposed from side surfaces 25c of the encapsulating layer 25. It should be understood that, according to requirements, after the singulation process, the shielding layer 22 is free from being exposed from the side surfaces 25c of the encapsulating layer 25 as an electronic package 2b shown in FIG. 2F-2.

In addition, in the subsequent process, as shown in FIG. 2G, the electronic package 2 can be disposed on an electronic device 29 such as a semiconductor chip, a packaging module, a circuit board, or other elements via the conductive elements 27.

Therefore, the manufacturing method of the electronic package 2, 2b of the present disclosure replaces the conventional metal cover 13 with the design of the shielding layer 22 and the shielding pillars 23, where the shielding layer 22, the shielding pillars 23 and the shielding portion 24 are grounded and connected to the circuit structure 20. Hence, compared with the prior art, the electronic package 2, 2b of the present disclosure can provide the electronic element 21 with the heat dissipation and the shielding effect without arranging a conventional metal cover after being disposed on the electronic device 29 (or circuit board), thereby facilitating the reduction of the use area of the electronic device 29 (or circuit board), so as to achieve the purpose of integration and meet the requirement of miniaturization of electronic products.

On the other hand, if the use area of the electronic device 29 (or circuit board) is maintained, after the electronic package 2, 2b is disposed on the electronic device 29 (or circuit board), there is no need to arrange a conventional metal cover, so as to arrange other functional electronic elements (not shown), so the functions of electronic products can be increased to facilitate the multifunctional purpose of electronic products.

Furthermore, as shown in FIG. 2G, the shielding portion 24 is arranged obliquely relative to the second surface 25b of the encapsulating layer 25, so that after the electronic package 2, 2b is disposed on the electronic device 29 (or circuit board), the circuit structure 20 is gradually decreased from the width D1 (from the side of the encapsulating layer 25) toward a width D2 (from the side of the conductive element 27). Therefore, the space of the electronic device 29 (or circuit board) around the circuit structure 20 can be increased to facilitate the arrangements of other functional electronic elements (not shown).

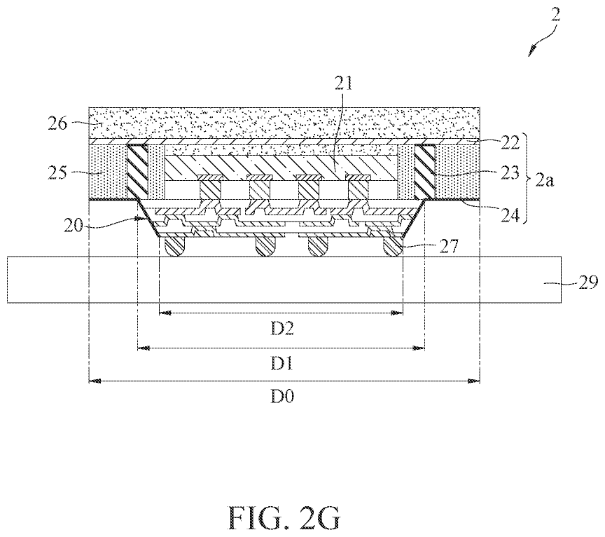

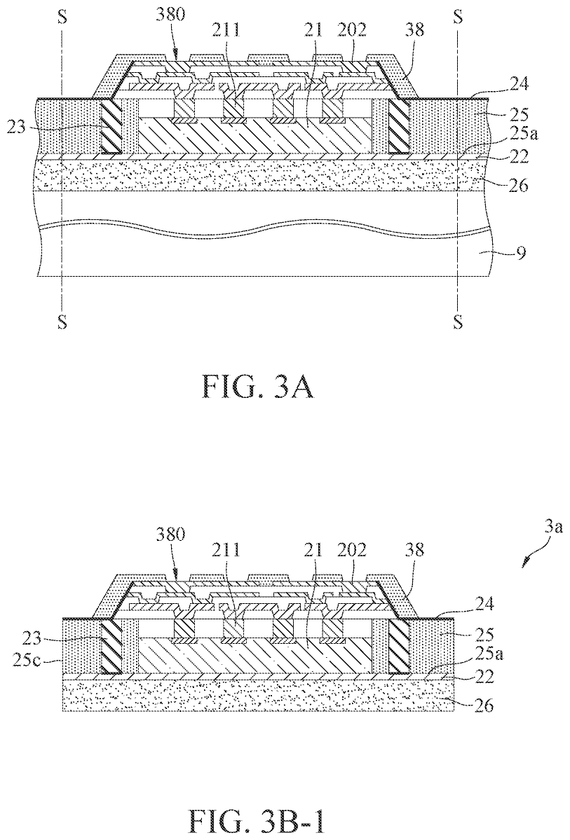

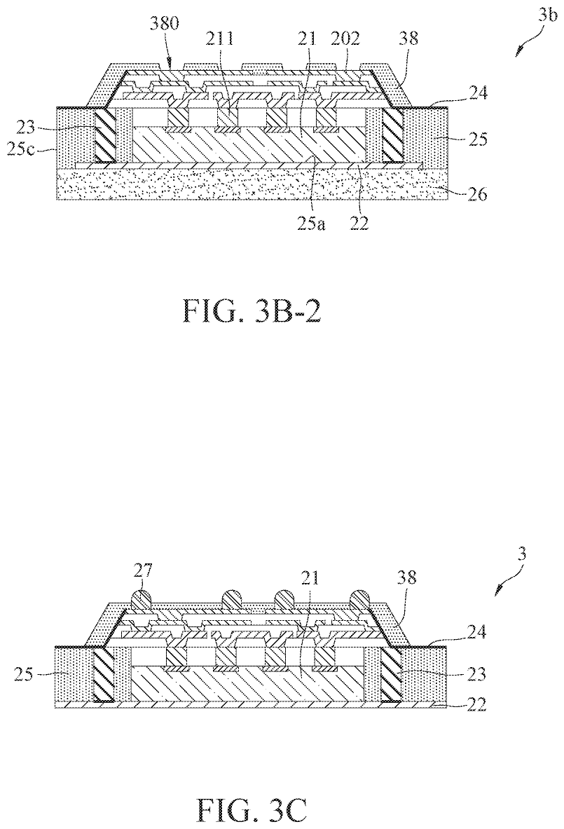

FIG. 3A to FIG. 3C are schematic cross-sectional views illustrating a method of manufacturing an electronic package 3, 3a, 3b according to a second embodiment of the present disclosure. The difference between the second embodiment and the first embodiment lies in additionally arranging an insulating protection layer 38, and the other manufacturing processes are substantially the same, so the similarities will not be repeated below.

As shown in FIG. 3A, continuing the process shown in FIG. 2D, the insulating protection layer 38 is formed on the outline of the circuit structure 20 (i.e., the side surfaces 20c and the outermost layer of the dielectric layer 200 and the circuit layer 201), so that the insulating protection layer 38 covers at least part of the shielding portion 24, and the plurality of electrical contact pads 202 are exposed from the insulating protection layer 38.

In an embodiment, the insulating protection layer 38 is made of materials such as polybenzoxazole (PBO), polyimide (PI), prepreg (PP), or other dielectric materials, even a solder mask.

Furthermore, the insulating protection layer 38 is formed with a plurality of openings 380, so that each of the electrical contact pads 202 is correspondingly exposed from each of the openings 380. Alternatively, the surface of the insulating protection layer 38 can be flush with the surfaces of the electrical contact pads 202 by a leveling process to expose each of the electrical contact pads 202.

In addition, in an embodiment, the bonding layer 213 can be omitted in the manufacturing process of FIG. 2A-1, so that the shielding layer 22 can be in contact with the electronic element 21.

As shown in FIG. 3B-1, proceeding the processes shown in FIG. 2E to FIG. 2F-1 to obtain a plurality of the electronic packages 3a of which the shielding portion 24 is at least partially embedded in the dielectric body (the insulating protection layer 38 and the dielectric layer 200 can be regarded as one body).

In an embodiment, the shielding layer 22 can be exposed (as shown in FIG. 3B-1) or not exposed (as the electronic package 3b shown in FIG. 3B-2) from the side surfaces 25c of the encapsulating layer 25 according to requirements.

In addition, the insulating base layer 26 can be removed as required while removing the carrier 9, such as the electronic package 3 shown in FIG. 3C, so as to expose the shielding layer 22.

Therefore, the manufacturing method of the electronic package 3, 3a, 3b of the present disclosure replaces the conventional metal cover 13 with the design of the shielding layer 22 and the shielding pillars 23, where the shielding layer 22, the shielding pillars 23 and the shielding portion 24 are grounded and connected to the circuit structure 20. Therefore, compared with the prior art, the electronic package 3, 3a, 3b of the present disclosure can provide the electronic element 21 with the heat dissipation and the shielding effect without arranging a conventional metal cover after being disposed on the electronic device 29 (or circuit board), thereby facilitating the reduction of the use area of the electronic device 29 (or circuit board), so as to achieve the purpose of integration and meet the requirement of miniaturization of electronic products.

On the other hand, if the use area of the electronic device 29 (or circuit board) is maintained, after the electronic package 3, 3a, 3b is disposed on the electronic device 29 (or circuit board), there is no need to arrange a conventional metal cover, so as to arrange other functional electronic elements (not shown), so the functions of electronic products can be increased to facilitate the multifunctional purpose of electronic products.

Furthermore, the shielding portion 24 is arranged obliquely relative to the second surface 25b of the encapsulating layer 25, so that after the electronic package is disposed on the electronic device 29 (or circuit board), the circuit structure 20 is gradually decreased from the width D1 (from the side of the encapsulating layer 25) toward the width D2 (from the side of the conductive element 27). Therefore, the space of the electronic device 29 (or circuit board) around the circuit structure 20 can be increased to facilitate the arrangements of other functional electronic elements (not shown).

The present disclosure also provides an electronic package 2, 2b, 3, 3a, 3b, which comprises: an encapsulating layer 25, an electronic element 21 embedded in the encapsulating layer 25, a shielding layer 22, a plurality of shielding pillars 23, and a circuit structure 20.

The encapsulating layer 25 has a first surface 25a and a second surface 25b opposing the first surface 25a.

The shielding layer 22 is formed on the first surface 25a of the encapsulating layer 25 to cover the electronic element 21.

The shielding pillars 23 are embedded in the encapsulating layer 25 and in communication with the first surface 25a and the second surface 25b to contact and connect the shielding layer 22.

The circuit structure 20 is formed on the second surface 25b of the encapsulating layer 25 and is electrically connected to the electronic element 21.

In one embodiment, a bonding layer 213 is formed between the shielding layer 22 and the electronic element 21.

In one embodiment, the shielding layer 22 is in contact with the electronic element 21.

In one embodiment, a width R of the shielding pillar 23 is greater than a thickness t of the shielding layer 22.

In one embodiment, the electronic element 21 is surrounded by the plurality of shielding pillars 23.

In one embodiment, a shielding portion 24 connected to the shielding pillars 23 is disposed on the circuit structure 20. For example, the shielding portion 24 is formed on the side surfaces 20c of the circuit structure 20. Alternatively, the shielding portion 24 is disposed obliquely relative to the second surface 25b of the encapsulating layer 25. Further, the electronic package 3 may comprise an insulating protection layer 38 covering at least part of the shielding portion 24.

In one embodiment, a maximum width D1 of the circuit structure 20 is less than a width DO of the second surface 25b of the encapsulating layer 25.

In view of the above, the electronic package of the present disclosure and manufacturing method thereof provide the design of the shielding layer and the shielding pillars, so that after the electronic package is disposed on an electronic device, the electronic package can provide heat dissipation and shielding effect to the electronic element without disposing a conventional metal cover. Therefore, the electronic package of the present disclosure is conducive to reduce the use area of the electronic device and achieve the purpose of integration, so that electronic products meet the requirement of miniaturization.

On the other hands, if the use area of the electronic device is maintained, when the electronic package is disposed on the electronic device, other functional electronic elements can be configured without disposing a conventional metal cover, so the function of electronic products can be increased to facilitate the multifunctional purpose of electronic products.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
an encapsulating layer having a first surface and a second surface opposing the first surface;
an electronic element embedded in the encapsulating layer;
a shielding layer formed on the first surface of the encapsulating layer and covering the electronic element;
a plurality of shielding pillars embedded in the encapsulating layer and in communication with the first surface and the second surface to contact and connect the shielding layer; and
a circuit structure formed on the second surface of the encapsulating layer and electrically connected to the electronic element.

2. The electronic package of claim 1, further comprising a bonding layer formed between the shielding layer and the electronic element.

3. The electronic package of claim 1, wherein the shielding layer is in contact with the electronic element.

4. The electronic package of claim 1, wherein a width of each of the plurality of shielding pillars is greater than a thickness of the shielding layer.

5. The electronic package of claim 1, wherein the electronic element is surrounded by the plurality of shielding pillars.

6. The electronic package of claim 1, further comprising a shielding portion disposed on the circuit structure and connected to the plurality of shielding pillars.

7. The electronic package of claim 6, wherein the shielding portion is formed on side surfaces of the circuit structure.

8. The electronic package of claim 6, wherein the shielding portion is arranged obliquely relative to the second surface of the encapsulating layer.

9. The electronic package of claim 6, further comprising an insulating protection layer covering at least part of the shielding portion.

10. The electronic package of claim 1, wherein a maximum width of the circuit structure is less than a width of the second surface of the encapsulating layer.

11. A method of manufacturing an electronic package, comprising:
forming a shielding layer on a carrier;
disposing an electronic element on the shielding layer, and forming a plurality of shielding pillars on the shielding layer, wherein the plurality of shielding pillars are in contact with and connected to the shielding layer;
forming an encapsulating layer on the shielding layer, wherein the electronic element and the plurality of shielding pillars are covered by the encapsulating layer, the encapsulating layer is defined with a first surface and a second surface opposing the first surface, and the encapsulating layer is bonded onto the shielding layer with the first surface of the encapsulating layer;
forming a circuit structure on the second surface of the encapsulating layer, wherein the circuit structure is electrically connected to the electronic element; and
removing the carrier.

12. The method of claim 11, further comprising forming a bonding layer between the shielding layer and the electronic element.

13. The method of claim 11, wherein the shielding layer is in contact with the electronic element.

14. The method of claim 11, wherein a width of each of the plurality of shielding pillars is greater than a thickness of the shielding layer.

15. The method of claim 11, wherein the electronic element is surrounded by the plurality of shielding pillars.

16. The method of claim 11, further comprising forming a shielding portion on the circuit structure, wherein the shielding portion is connected to the plurality of shielding pillars.

17. The method of claim 16, wherein the shielding portion is formed on side surfaces of the circuit structure.

18. The method of claim 16, wherein the shielding portion is arranged obliquely relative to the second surface of the encapsulating layer.

19. The method of claim 16, further comprising forming an insulating protection layer to cover at least part of the shielding portion.

20. The method of claim 11, wherein a maximum width of the circuit structure is less than a width of the second surface of the encapsulating layer.
